(19) United States
(12) Patent Application Publication
(10) Pub. No.: US 2016/0149545 A1
(43) Pub. Date: May 26, 2016

(54) CIRCUITS AND METHODS PROVIDING ATTENUATION

(71) Applicant: QUALCOMM Incorporated, San Diego, CA (US)

(72) Inventor: Edward Robert Deak, Wake Forest, NC (US)

(21) Appl. No.: 14/851,982

(22) Filed: Sep. 11, 2015

Related U.S. Application Data
(60) Provisional application No. 62/083,558, filed on Nov. 24, 2014.

(51) Int. Cl. H03F 3/45

(52) U.S. Cl. CPC H03F 3/45076; H03F 2203/45116; H03F 2203/45336; H03F 2200/156

(57) ABSTRACT

An apparatus and method are disclosed for providing attenuation. An operational amplifier is in a non-inverting gain configuration with its output provided to a voltage divider having a first resistive component and a second resistive component. The first resistive component includes a plurality of resistors in series, and a feedback loop of the amplifier is defined at various points within the series of resistors and has a plurality of switches associated with each of the resistors in series. The output voltage is defined by the second resistive component. A switch of the plurality of switches may be selected to be closed to define a gain of the amplifier, thereby setting the attenuation ratio the circuit.

### CROSS REFERENCE TO RELATED APPLICATIONS

The present application claims priority to and the benefit of the U.S. Provisional Patent Application No. 62/083,558, filed Nov. 24, 2014 which is hereby incorporated by reference in its entirety.

### TECHNICAL FIELD

This application relates to attenuators and, more specifically, to attenuators employing amplifier feedback loops.

### BRIEF DESCRIPTION OF THE DRAWINGS

FIG. 1 is an illustration of an example embodiment of a precision attenuator circuit.

FIG. 2 is an illustration of an example circuit, adapted according to one embodiment.

FIG. 3 is a flow diagram of an example method of providing an attenuated signal, according to one embodiment.

### DETAILED DESCRIPTION

Disclosed herein are embodiments of a circuit and a method for providing attenuation of an input voltage. In one example, an output voltage of the attenuator is received by an analog to digital converter (ADC), which is designed to receive the output voltage within a precise range of values. Accordingly, in this example, the method and circuit provide for precise attenuation of the input voltage to stay within the design specification of the ADC.

One example embodiment includes an operational amplifier that is set in a positive gain configuration. The output of the amplifier feeds a series of resistors that are in communication with a ground or other low-voltage. The series of resistors forms a resistor divider, where a resistive portion R1 and a resistive portion R2 are in series so that an output voltage is defined by the voltage drop over R2. The resistive portion R1 is coupled between the output of the amplifier and R2, and the resistive portion R2 is coupled between R1 and ground.

The resistive portion R1 includes a series of individual resistive elements, where each one of the individual resistive elements is associated with an individual, selectable switching element coupled to the feedback input of the amplifier. It is desired that the attenuation ratio provided by R1 and R2 is equal to a particular amount. However, process variation in the manufacture of the individual resistive elements that make R1 and R2 may cause the resulting attenuation ratio to differ from the desired attenuation ratio when gain of the amplifier is at 1.

The example embodiment provides the individual, selectable switches so that one of the switches may be closed (and the other ones left open) to define a voltage seen by the feedback loop of the amplifier. A larger voltage drop between the output of the amplifier and the particular, selected switch results in a higher gain at the output of the amplifier and a larger voltage drop across R1 (and across R2 as well). Similarly, a smaller voltage drop between the output of the amplifier and the particular, selected switch result in a smaller gain at the output of the amplifier and a smaller voltage drop across R1 (and across R2 as well).

In one example use case, the attenuator circuit is tested after manufacture. With a known input voltage, a testing machine closes a switch and measures the resulting output voltage across R2. The testing machine repeats the process of selecting a switch and measuring the resulting output voltage for each of the individual, selectable switches (or a subset thereof) and then determines which switch provides an output voltage that corresponds to the desired attenuation ratio. The attenuator circuit may be provided as part of a system-on-a-chip (SOC), and the testing machine saves data to a memory of the SOC that identifies the selected switch. Later, upon power up of the SOC, the SOC accesses the data in the memory and then sets the attenuator according to the data so that the particular switch is closed during operation, thereby providing the desired attenuation ratio.

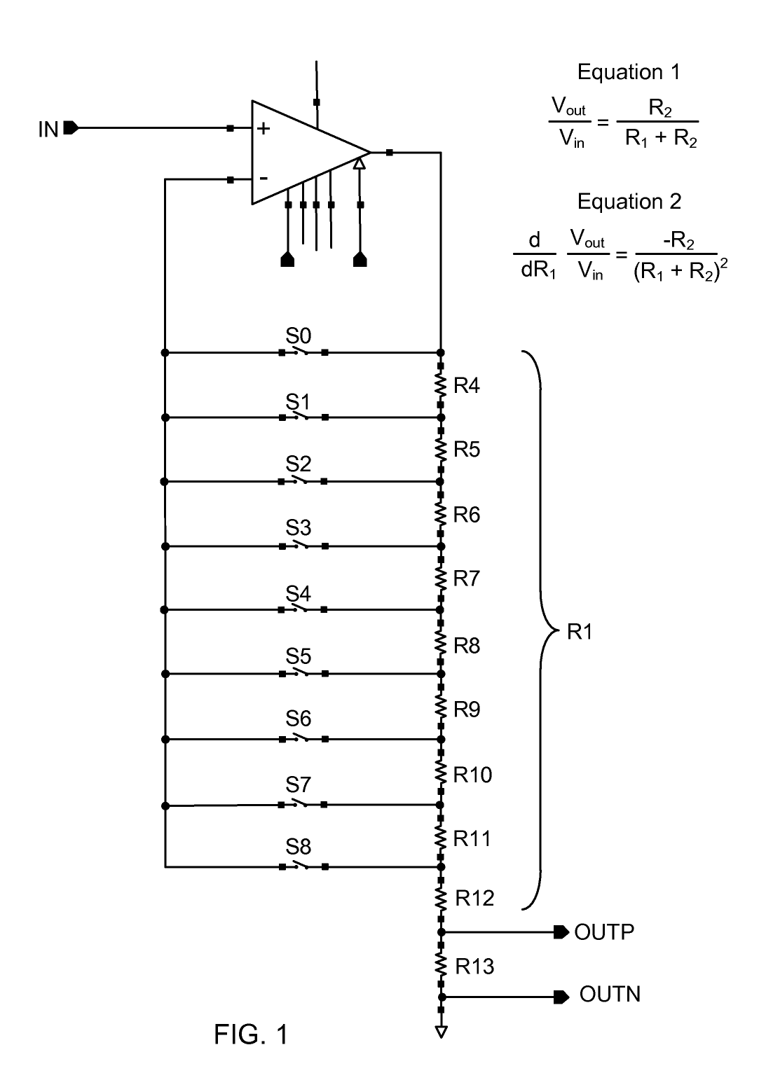

The embodiments described herein are illustrative examples, and do not limit the scope of embodiments. For example, an attenuator circuit may provide an output voltage to an ADC, but other embodiments may provide an output voltage to a component other than an ADC. Furthermore, the embodiment of FIG. 1 provides for a specific attenuation ratio, but the scope of embodiments is not limited to any particular attenuation ratio, and in fact, other embodiments may be adapted for use with any appropriate attenuation ratio. Also, the values of the resistive elements within the resistive components R1 and R2 may be adapted as appropriate to provide a desired attenuation ratio.

One example embodiment of a precision attenuator circuit is shown in FIG. 1. The circuit of FIG. 1 includes an operational amplifier that has a voltage input (IN at “+”), an amplifier output (amp_out), and a feedback input (“−”). The circuit also includes a resistor divider made up of a first resistive component (R1) and a second resistive component (R2). The resistive component R1 is made up of a series of resistive elements R4-R12, where each of the resistive elements is labeled 0.5 R₀, except for one element which is labeled 22 R₀. R₀ is a designation for a unit of resistance, where each of the resistive elements in series provides for half of a unit resistance, except for the one at the bottom which provides for 22 units of resistance. The second resistive component, R2, provides for one unit of resistance and also defines the voltage output (OUTP−OUTN). As explained in more detail below, the present example circuit is designed to provide attenuation at a ratio of 1/25.

Continuing with the example, each of the resistive elements R4-R11 is coupled to the feedback input of the operational amplifier by a respective switch (S0-S8). R12 is not coupled to the feedback loop in the same way that R4-R11 are coupled because the voltage drop across R12 is not seen by the feedback loop; nevertheless, R12 is part of R1. A switch may be selected, out of the multitude of switches, to be closed thereby defining the feedback loop for the operational amplifier. If switch S0 is the only switch that is closed, the operational amplifier is a voltage follower and has a gain of 1. The gain affects the current through the voltage divider circuit, thereby establishing an output voltage across R2.

If switch S1 is instead the switch that is closed, then the feedback loop of the operational amplifier includes resistive element R4, which decreases the feedback voltage incrementally and causes the gain to increase to a value above 1. It also causes the current through the voltage divider to increase as well. Maximum gain in the circuit of FIG. 1 is achieved by selecting switch S8, which also produces the maximum current through the voltage divider in this example. Thus, in this example, the resistor divider using R1 and R2 over-attenuates the signal, and the gain of the amplifier can be adjusted from a minimum of 1 up to a higher value to set the attenuation at a desired ratio.

According to Equation 1 (see the drawings), the voltage ratio of 1/25 can be achieved when R1 is equal to 24 resistive units, and R2 is equal to one resistive unit. However, as shown in FIG. 1, the total value of the resistive elements within component R1 is equal to 26 resistive units. Assuming that the values of the resistive elements are accurate (in other words, there is no manufacturing process variation), then an attenuation ratio of approximately 1/25 can be achieved by closing switch S4, which increases the gain of the amplifier to be a value greater than one. The embodiment of FIG. 1 is designed so that, whether a process variation causes the actual value of R2 to be higher or lower than desired, a switch either above or below S4 can be selected to compensate for that process variation.

Equation 2 shows that the rate of change of R1 has a greater effect on the attenuation ratio than does a change in R2 when R1 is large. The circuit of FIG. 1 is designed so that selection of a particular switch among S0-S8 is analogous to changing a value of R1. In other words, selection of a desired switch within the circuit of FIG. 1 has a fine impact on the attenuation ratio, and the presence of a multitude of resistive elements and corresponding switches within R1 provides a likelihood that the desired attenuation ratio may be achieved to within a tight precision by selection of one of the switches.

The explanation above assumes no manufacturing process variation. In other examples, process variation is a substantial possibility, and it is not known beforehand how process variation might have affected the different values of the resistive elements within R1 and the resistive elements within R2. But a given switch may be chosen to provide a desired output attenuation (in this case, a ratio of 1/25).

In some example embodiments, each of the resistive elements in series R4-R11 are one-half of a unit resistance (0.5R0) and are made by including two unit resistors in parallel. Continuing with the example, resistive element R12 has a value of 22 R0 and is made by connecting 22 unit resistors in series. However, the scope of embodiments is not limited to any particular manufacturing technique. With a large number of resistors in use in the circuit of FIG. 1, there is a possibility that one or more of those unit resistors might be affected by manufacturing process variation in some way.

Consider an example in which R2 is relatively small compared to its desired value. In such a scenario, it may be appropriate to choose one of the switches S4-S8 to increase the amount of gain at the amplifier, thereby increasing the voltage across R2 to correspond to a desired attenuation ratio.

Consider another example in which R2 is relatively large compared to its desired value. In this scenario, it may be appropriate to choose one of the switches S0-S4 to set the amount of gain at the amplifier close to 1, thereby decreasing the voltage across R2 to correspond to a desired attenuation ratio. In both of the examples above, factors affecting which of the switches S0-S8 should be chosen include: 1) the amount of deviation by R2 from its desired value and 2) whether the deviation makes R2 larger or smaller. Another factor affecting which of the switches should be chosen may include, for example, manufacturing process variation affecting any of the resistors within R1.

Accordingly, one example manufacturing technique may include iteratively closing one of the switches at a time until a desired output attenuation is achieved. This is a calibration step that matches one of the switches to the desired output attenuation. Once it is determined which one of the switches corresponds to the desired attenuation, data may be saved in memory that identifies the switch. Upon power up of the circuit, logic reads the value from memory and selects the switch identified by the value. Each semiconductor die may have different manufacturing process variations, and so any given manufactured die may use higher or lower gain from the operational amplifier to account for process variation differences. However, the embodiment shown above allows a range of gain to be achieved so that a precise attenuation may be provided to a downstream circuit, such as an ADC. The implementation of FIG. 1 may be used for a precision telemetry application that uses a 1/25 attenuation, and the implementation achieves less than 0.5% error of the attenuated signal over a mismatch range of +/−5% using a total of 39 active resistor elements.

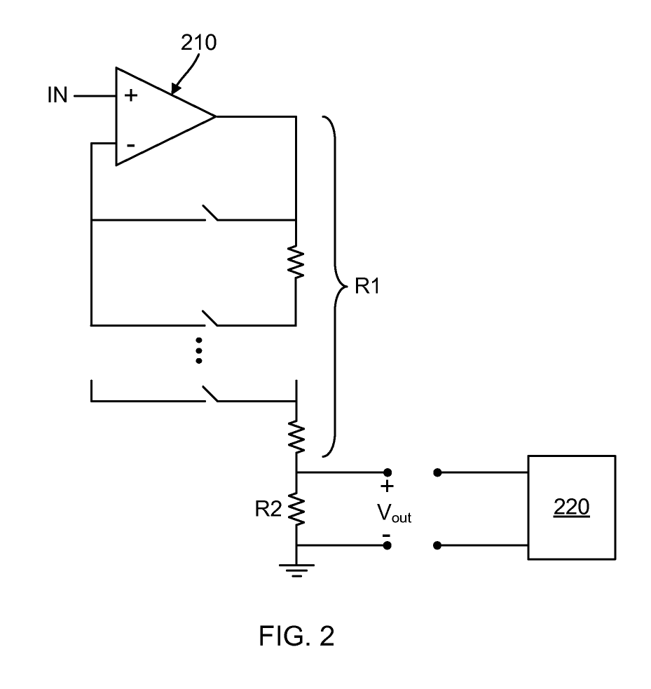

FIG. 2 is an illustration of an example circuit, adapted according to one embodiment. The circuit of FIG. 2 is similar to the circuit of FIG. 1, and the circuit of FIG. 2 shows that the number of resistive elements within R1 can be scaled for a given application. Amplifier 210 is in a non-inverting gain configuration, where the minimum gain at its output is 1, and the gain can be increased by selecting one of the switches in the feedback loop. The switches are shown here as simple open-and-close switches, and some embodiments may be implemented with transistors or other appropriate components.

The attenuator of FIG. 2 provides an output voltage Vout that is defined across resistor R2. The attenuated output voltage, Vout, is provided to a downstream component 220. As noted above, the downstream component 220 may include an ADC, though the scope of embodiments may include any appropriate component that receives an attenuated voltage. In some examples, the circuit of FIG. 2 is included in a system-on-a-chip or other integrated circuit package.

The scope of embodiments is not limited to any particular manufacturing process. Nevertheless, the following example illustrates an embodiment in which a 0.18 μm process is used to manufacture the system-on-a-chip. This example relaxes a resistor matching requirement to +/−8%, and a unit resistor area (W*L) is equal to 2 μm². Such an example may include a total resistor area of 96 μm² using 48 individual resistors in a circuit according to FIG. 2 having four more 0.5R₀ resistive elements in R1 and four more switches than in FIG. 1. This example uses 0.2*R₀ adjustment steps, rather than 0.5% in the example above, so the total number of resistors is 48 rather than 39. A less precise resistor matching requirement of plus or −8% may be used in this example because a circuit according to the architecture of FIG. 2 uses the selection of particular switches to overcome the resistor matching requirement to provide a desired precision of 5% in the attenuation ratio. In this example, additional resistors are relatively cheap, so that more accuracy burden can be placed onto the circuit.

By contrast, another circuit using a conventional potentiometer (not shown) with a 0.04% matching requirement and 1/25 attenuation requirement has a unit resistor area of 636.4 μm² and a total resistor area of 15,910 μm² in order to achieve the same precision of 5% in the attenuation ratio. In other words, a circuit such as that shown in FIGS. 1 and 2 may be used instead of a traditional potentiometer to provide a greater degree of precision and to lower an amount of resistor space in the circuit.

One advantage to the circuits of FIGS. 1 and 2 is that changes in R1 may be achieved using a fewer number of total resistive elements than a conventional architecture which might adjust R2 instead. Another advantage is that the switches S0-S8 do not carry current, and thus do not suffer temperature drift during operation.

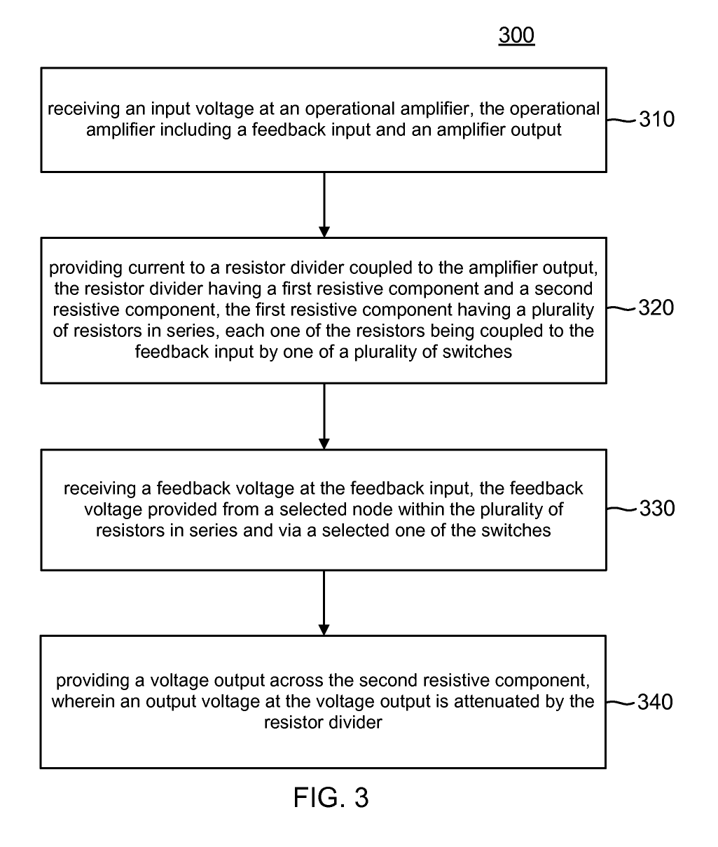

A flow diagram of an example method 300 of providing an attenuated signal is illustrated in FIG. 3. In one example, method 300 is performed by the circuits of FIGS. 1 and 2, to receive an input voltage, and provide an output voltage by a voltage divider, where the output voltage is affected by a gain of an amplifier. Method 300 may be performed in a system, such as a system-on-a-chip or other chip package, that uses an attenuated voltage at a component, such as an ADC.

At action 310, the amplifier receives an input voltage. In this example, the amplifier is an operational amplifier that includes a voltage input, a feedback input, and an output. The amplifier is arranged in a non-inverting gain configuration, where the input voltage is received at its + input, the feedback loop terminates at its − input, and the amplifier output is in communication with the voltage divider (as described further below).

At action 320, the amplifier provides current to the resistor divider. The resistor divider has a first resistive component and a second resistive component, where examples are shown above at FIGS. 1 and 2 as R1 and R2. The first resistive component has a plurality of resistors in series, where each one of the resistors is coupled to the feedback input by one of the plurality of switches.

In the example of FIGS. 1 and 2, the first resistive component is illustrated by R1, which includes a plurality of resistors in series. Each of the resistors in series is associated with a switch (such as a transistor). During operation of the circuit, one of the switches is closed, thereby defining the feedback loop of the amplifier.

At action 330, the amplifier receives the feedback voltage at its feedback input. The node within the first resistive component at which the feedback input is provided is determined by which switch is closed. In an example in which one of the switches is closed at any given time, the closed switch provides the voltage from a point between two of the resistors in series to the feedback input of the amplifier. This is illustrated in FIGS. 1 and 2, where the feedback voltage may be provided from any point between the amplifier output and the node between R11 and R12.

At action 340, the circuit provides a voltage output across the second resistive component. In the example of FIGS. 1 and 2, the output voltage is defined across R2. The output voltage is thus an attenuated version of the input voltage having been reduced by the voltage divider that is formed by R1 and R2.

The scope of embodiments is not limited to the specific method shown in FIG. 4. Other embodiments may add, omit, rearrange, or modify one or more actions. For instance, the actions 310-340 in some embodiments are not performed as a series, but rather, are performed substantially simultaneously and ongoing during operation of the circuit. As the input voltage varies, the attenuation ratio is held constant, though the output voltage may vary as well by operation of the feedback loop of the operational amplifier.

Furthermore, some embodiments may also include a calibration step during manufacturing to determine an appropriate switch to close to provide the desired attenuation ratio. Although not illustrated in the figures above, manufacturing machinery may provide an input voltage and sample the value of Vout to test the value of Vout attributed to each one of the switches. For instance, the algorithm may include closing one switch while the others are opened, and subsequently opening the first switch and closing the second switch while the other switches are opened, subsequently opening the first and second switch and closing a third switch while the other switches are opened, and on and on. For each one of the switches being closed, Vout is measured, and the value of Vout that corresponds to the desired attenuation ratio is associated with a particular switch. Therefore, the calibration process identifies the particular switch associated with the desired attenuation ratio. Information identifying the particular switch is stored in memory (not shown) and may be accessed later. At power up or some other appropriate time, logic on the system-on-a-chip or other chip package accesses the data from memory and closes the identified switch to provide the desired attenuation ratio in the circuit.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. A circuit comprising:
an operational amplifier having a voltage input, and amplifier output, and a feedback input; and
a resistor divider having a first resistive component and a second resistive component, the first resistive component coupled to the amplifier output, wherein the first resistive component comprises a plurality of resistive elements in series, each of the resistive elements being associated with a respective selectable switching component coupled to the feedback input of the operational amplifier, and further wherein the second resistive component is in series with the first resistive component and configured to provide a voltage output for the circuit.

2. The circuit of claim 1, configured to provide an attenuation of the input voltage signal by a factor of 1/25.

3. The circuit of claim 1, wherein a subset of the plurality of the resistive elements is configured to provide one half unit of resistance each, and one of the resistive elements configured to provide a plurality of units of resistance, and the second resistive component is configured to provide one unit of resistance.

4. The circuit of claim 1, wherein each selectable switching component is further coupled to a respective node in a series of the plurality of resistive elements.

5. The circuit of claim 1, further comprising an analog to digital converter having an input coupled to the voltage output for the circuit.

6. The circuit of claim 1, where the operational amplifier is held in a non-inverting gain configuration.

7. The circuit of claim 1, configured so that only one of the selectable switching components is closed at a given time.

8. The circuit of claim 1, wherein a feedback loop of the operational amplifier is configurable to include any one of the selectable switching components associated with the resistive elements or a switch that bypasses the first resistive component within the feedback loop.

9. The circuit of claim 8, wherein a gain of the operational amplifier is 1 when the switch that bypasses the first resistive component is closed and the other switches are opened.

10. A method comprising:
receiving an input voltage at an operational amplifier, the operational amplifier including a feedback input and an amplifier output;
providing current to a resistor divider coupled to the amplifier output, the resistor divider having a first resistive component and a second resistive component, the first resistive component having a plurality of resistors in series, each one of the resistors being coupled to the feedback input by one of a plurality of switches;
receiving a feedback voltage at the feedback input, the feedback voltage provided from a selected node within the plurality of resistors in series and via a selected one of the switches; and
providing a voltage output across the second resistive component, wherein an output voltage at the voltage output is attenuated by the resistor divider.

11. The method of claim 10, wherein the output voltage has an attenuation ratio based on which one of the switches is the selected one of the switches.

12. The method of claim 10, wherein the selected one of the switches is closed to provide the feedback voltage, and the selected one of the switches does not carry current.

13. The method of claim 10, wherein a gain of the operational amplifier is at least one.

14. The method of claim 10, further comprising:
accessing a stored value from memory during power up of a semiconductor circuit, the stored value indicating the selected one of the switches out of the plurality of switches;
selecting the selected one of the switches in response to accessing the stored value.

15. The method of claim 10, wherein the resistor divider provides an attenuation of 1/25.

16. A system comprising:
means for receiving an input voltage and a feedback voltage and for adjusting a first output voltage in response to the input voltage and the feedback voltage;
means for providing a second output voltage, wherein the means for providing the second output voltage includes a first resistive component and a second resistive component, the first resistive component coupled to the first output voltage, wherein the first resistive component comprises a plurality of resistive elements in series, and further wherein the second resistive component is in series with the first resistive component and configured to provide the second output voltage; and
means for defining the feedback voltage, wherein the means for defining the feedback voltage includes a plurality of selectable switching components, further wherein each of the resistive elements is associated with a respective selectable switching component coupled to a feedback input of the means for receiving the input voltage.

17. The system of claim 16, wherein a subset of the plurality of resistive elements is configured to provide one half unit of resistance each, and one of the resistive elements configured to provide multiple units of resistance, and the second resistive component is configured to provide one unit of resistance.

18. The system of claim 16, wherein the means for receiving the input voltage comprises an operational amplifier arranged in a non-inverting gain configuration.

19. The system of claim 16, further comprising an analog to digital converter having an input coupled to the second output voltage.

20. The system of claim 16, wherein a feedback loop of the means for receiving the input voltage is configurable to include any one of the selectable switching components associated with the resistive elements or a switch that bypasses the first resistive component within the feedback loop.
